(19) United States
(12) Patent Application Publication
(10) Pub. No.: US 2026/0271321 A1
(43) Pub. Date: Sep. 10, 2026

(54) TRANSISTORS AND THE METHODS OF FORMING THE SAME

(71) Applicant: Taiwan Semiconductor Manufacturing Co., Ltd., Hsinchu (TW)

(72) Inventors: Wan-Yi Kao, Baoshan Township (TW); ChunYao Wang, Zhubei City (TW); Tze-Liang Lee, Hsinchu (TW)

(21) Appl. No.: 19/228,351

(22) Filed: Jun. 4, 2025

Related U.S. Application Data
(60) Provisional application No. 63/769,281, filed on Mar. 10, 2025.

(51) Int. Cl. H10D 30/01; H10D 30/00

(52) U.S. Cl. CPC H10D 30/0196; H10D 30/508

(57) ABSTRACT

A method includes forming a dummy gate stack, forming gate spacers on opposing sides of the dummy gate stack, forming a contact etch stop layer, with the gate spacers being in the contact etch stop layer, forming an inter-layer dielectric over the contact etch stop layer, recessing the dummy gate stack and the gate spacers to form a recess in the inter-layer dielectric, and depositing a protection layer. The protection layer comprises a portion in the recess. The method further includes etching the protection layer to leave a protection layer in the recess, removing the dummy gate stack to extend the recess downwardly, and forming a replacement gate stack in the recess.

### PRIORITY CLAIM AND CROSS-REFERENCE

This application claims the benefit of the following provisionally filed U.S. Patent application: Application No. 63/769,281, filed on Mar. 10, 2025, and entitled “VERTICAL LOW-K GATE SPACER,” which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 9C, 10A, 10B, 11-19, 20A, 20B, and 21-22, 23A, and 23B illustrate the views of intermediate stages in the formation of nanostructure transistors in accordance with some embodiments.

FIGS. 24-26 illustrate nanostructure transistors in accordance with alternative embodiments.

FIG. 27 illustrates a process flow for forming a nanostructure transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All Around (GAA) transistor (also referred to as a nanostructure transistor) and the method of forming the same are provided in accordance with some embodiments. The formation of the GAA transistor includes forming a multilayer stack including semiconductor nanostructures and sacrificial layers, and forming a dummy gate stack and gate spacers on the multilayer stack. The dummy gate stack and the gate spacers are recessed, and a dielectric protection layer is formed in the recess, followed by laterally thinning the gate spacers. The dummy gate stack and the sacrificial layers are then removed, and a replacement gate stack is formed.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

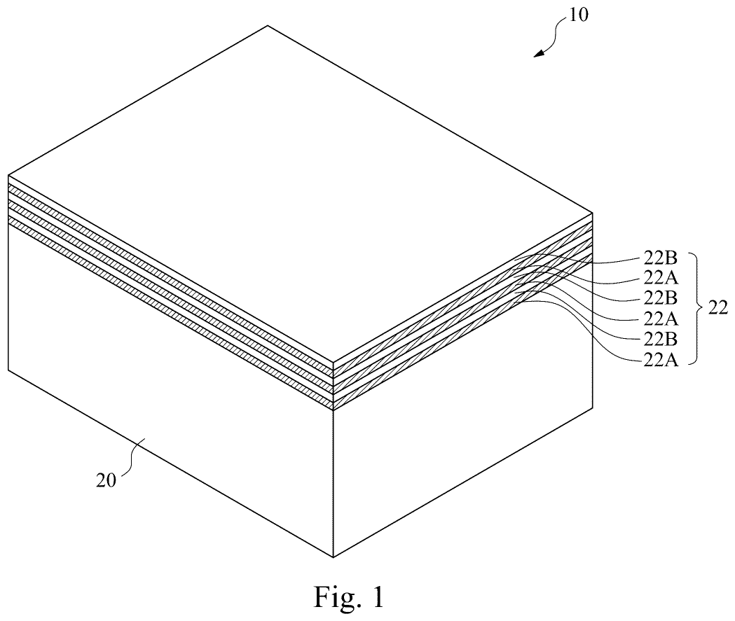

FIGS. 1-4, 5A, 5B, 6A, 6B, 7A, 7B, 8A, 8B, 9A, 9B, 9C, 10A, 10B, 11-19, 20A, 20B, and 21-22, 23A, and 23B illustrate the intermediate stages in the formation of a nanostructure transistor in accordance with some embodiments. The corresponding processes are also reflected schematically in the process flow as shown in FIG. 27.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 27. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there are some pad oxide layer(s) and hard mask layer(s) (not shown) formed over multilayer stack 22. These layers are patterned, and are used for the subsequent patterning of multilayer stack 22.

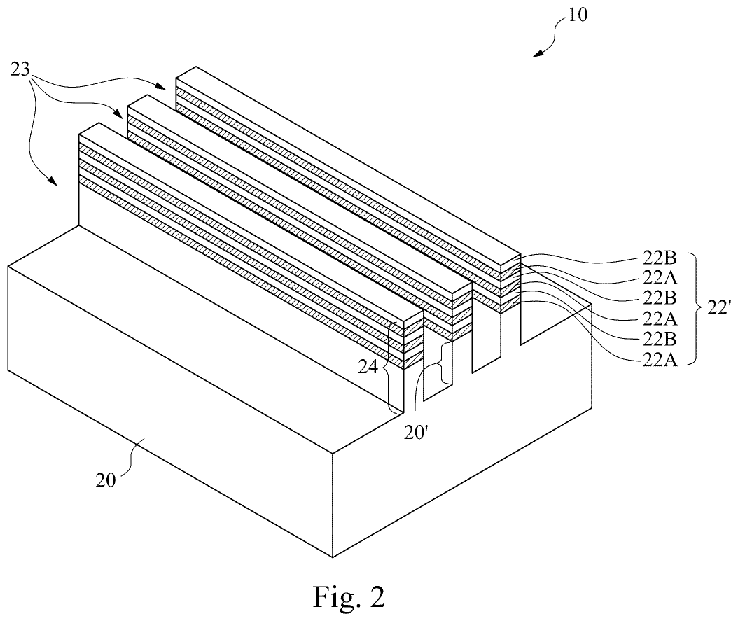

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 27. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

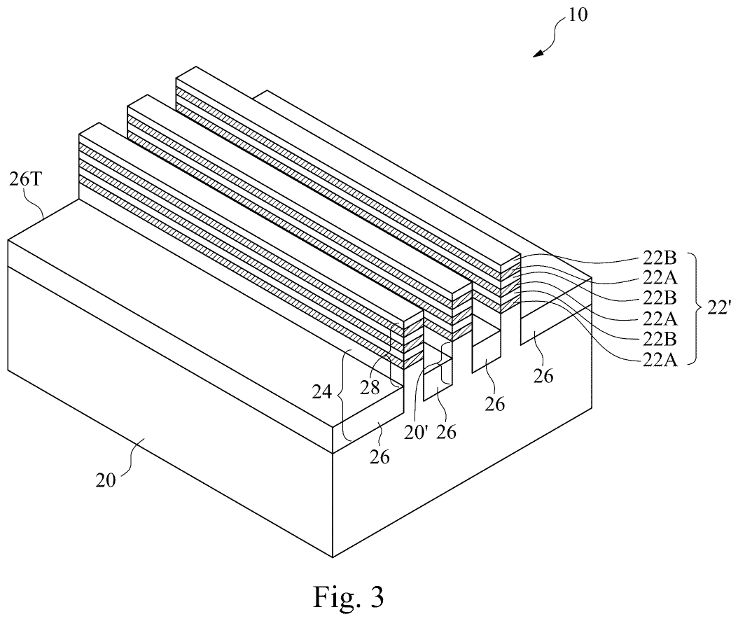

FIG. 3 illustrates the formation of isolation regions 26, which are also referred to as Shallow Trench Isolation (STI) regions throughout the description. The respective process is illustrated as process 206 in the process flow 200 shown in FIG. 27. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. The respective process is also illustrated as process 206 in the process flow 200 shown in FIG. 27. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

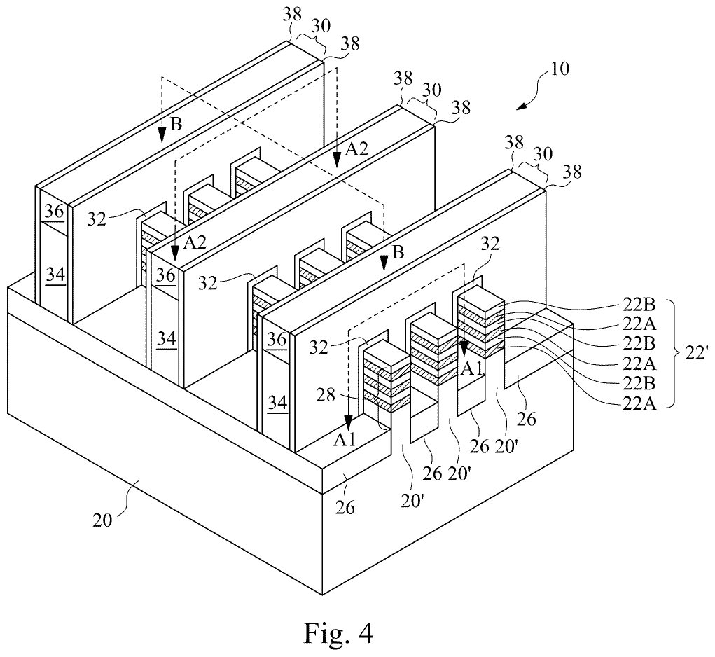

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 27. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon oxy-carbo-nitride (SiOCN), silicon nitride (SiN), silicon oxide (SiO₂), silicon carbo-nitride (SiCN), silicon oxynitride (SiON), or the like, and may have a single-layer structure or a multilayer structure including a plurality of dielectric layers. In accordance with some embodiments, gate spacers 38 comprise SiOCN, with the atomic percentage of the nitrogen being lower than about 5 percent. The gate spacers 38 may comprise a low-k dielectric material, which may also comprise SiOCN. The formation process of gate spacers 38 may include depositing one or a plurality of dielectric layers, and then performing an anisotropic etching process(es) on the dielectric layer(s). The remaining portions of the dielectric layer(s) are gate spacers 38.

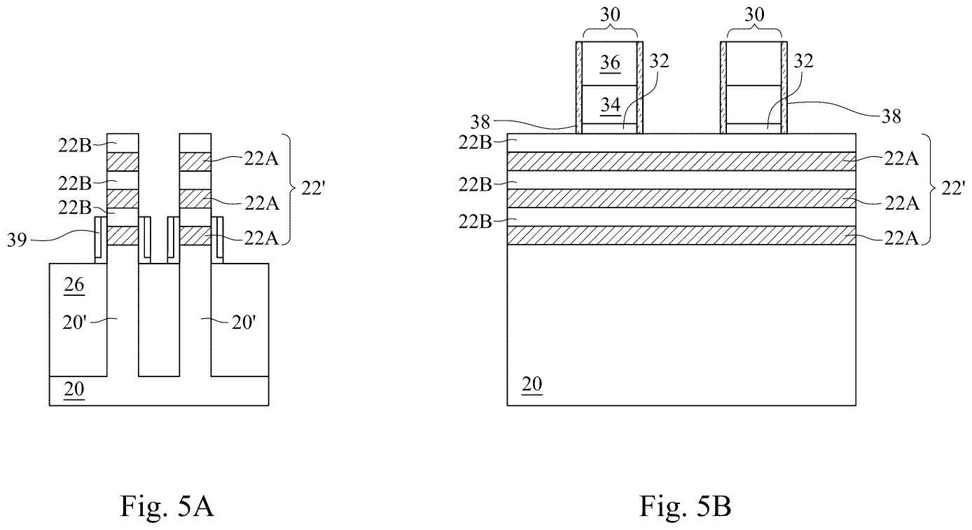

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28. Fin spacers 39 are also illustrated.

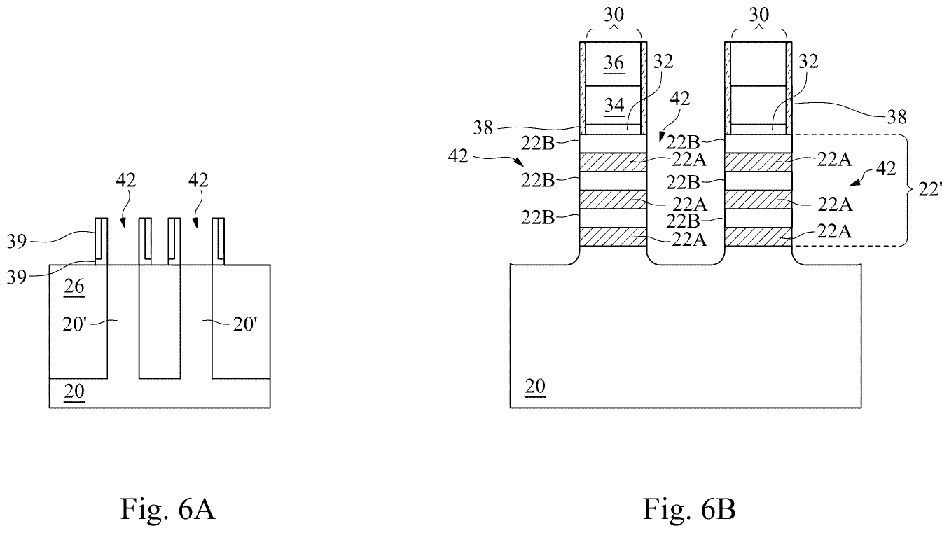

Referring to FIGS. 6A and 6B, the portions of protruding fins 28 (FIG. 4)(that are not directly underlying dummy gate stacks 30 and gate spacers 38 are recessed through an etching process to form recesses 42. The respective process is illustrated as process 210 in the process flow 200 shown in FIG. 27. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20'. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

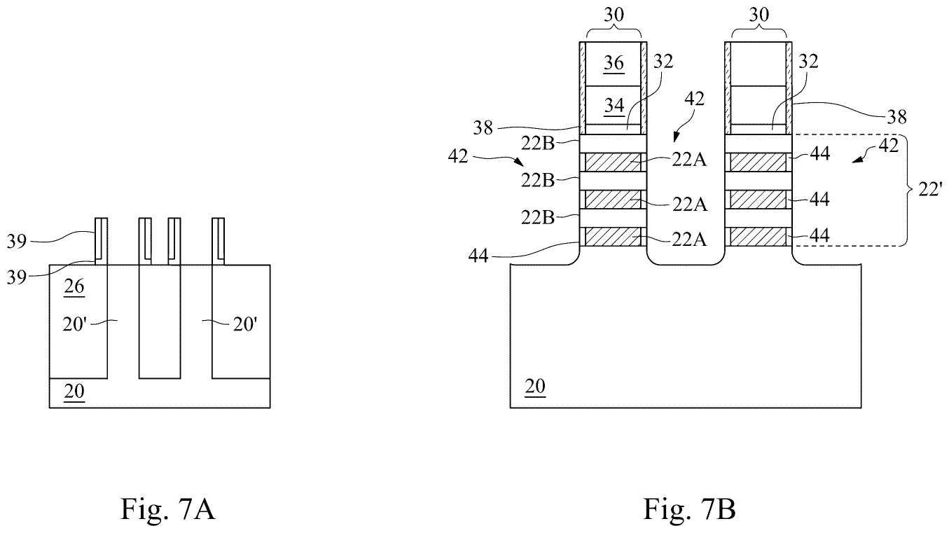

Referring to FIGS. 7A and 7B, inner spacers 44 are formed. The formation process may include laterally recessing sacrificial semiconductor layers 22A to form lateral recesses (occupied by inner spacers 44), which are recessed from the edges of the respective overlying and underlying nanostructures 22B. The lateral recessing of sacrificial semiconductor layers 22A may be achieved through a wet etching process, an isotropic dry etching process, or a combination of a dry etching process and a wet etching process.

Inner spacers 44 are then formed in the lateral recesses. The respective process is illustrated as process 212 in the process flow 200 shown in FIG. 27. The formation process incudes depositing a dielectric spacer layer extending into the lateral recesses, and performing an etching process to remove the portions of dielectric spacer layer outside of lateral recesses, thus leaving inner spacers 44 in the recesses. Inner spacers 44 may be formed of or comprise SiOCN, SiON, SiOC, SiCN, or the like.

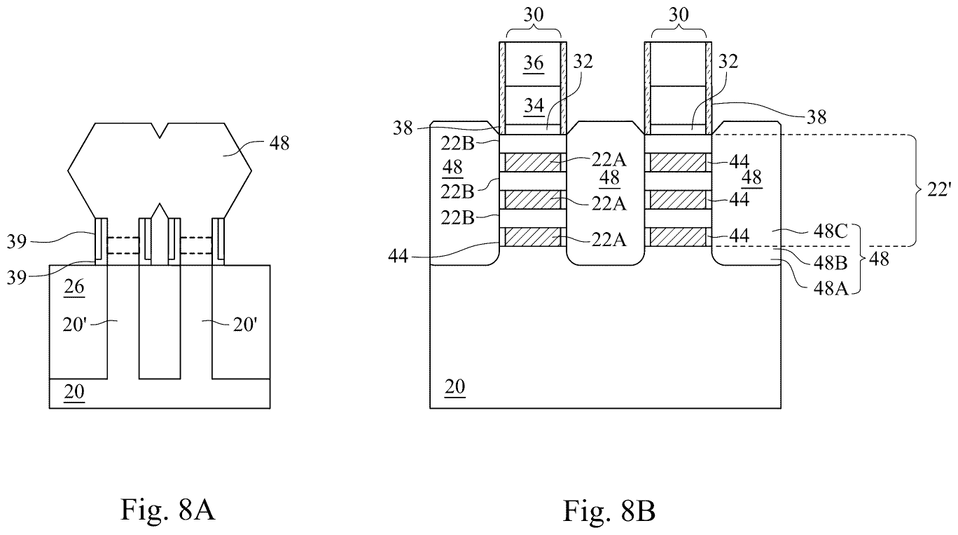

Referring to FIGS. 8A and 8B, epitaxial source/drain regions 48 are formed in recesses 42 through selective epitaxy growth. The respective process is illustrated as process 214 in the process flow 200 shown in FIG. 27. Depending on whether the resulting FinFET is a p-type FinFET or an n-type FinFET, a p-type or an n-type impurity may be in-situ doped with the proceeding of the epitaxy. For example, when the resulting FinFET is a p-type FinFET, epitaxial source/drain regions 48 may comprise silicon germanium boron (SiGeB), silicon boron (SiB), or the like. Conversely, when the resulting FinFET is an n-type FinFET, epitaxial source/drain regions 48 may comprise silicon phosphorous (SiP), silicon carbon phosphorous (SiCP), or the like.

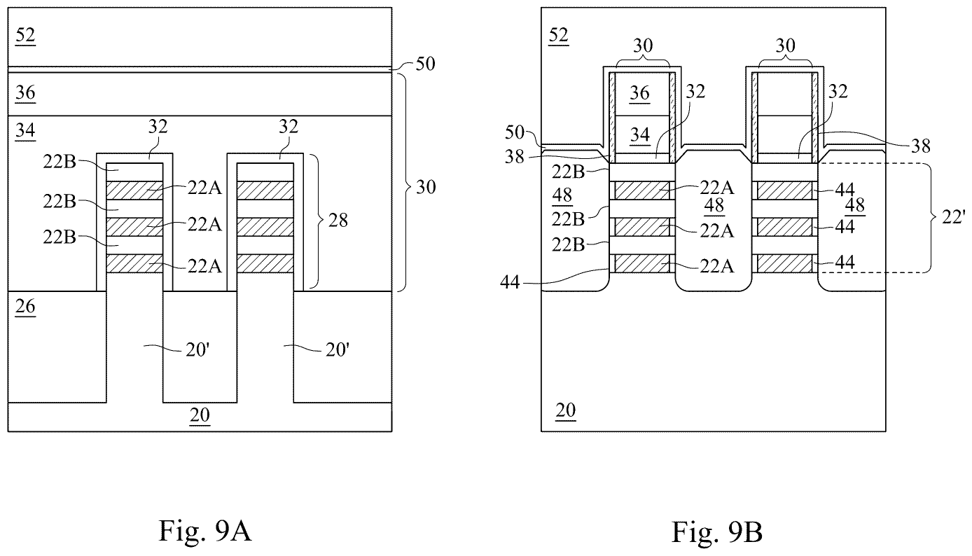

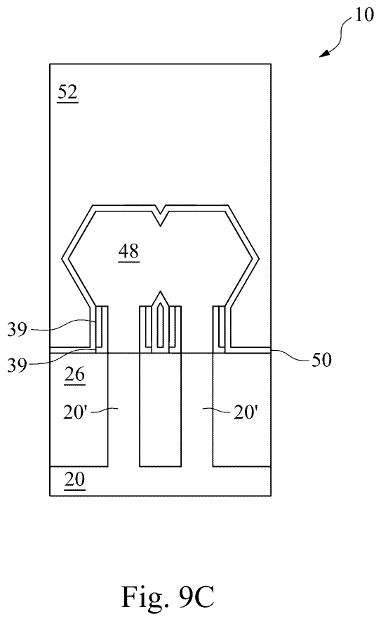

FIGS. 9A, 9B, and 9C illustrate the cross-sectional views of the structure after the formation of Contact Etch Stop Layer (CESL) 50 and Inter-Layer Dielectric (ILD) 52. FIGS. 9A, 9B, and 9C are obtained from the same cross-section same as the cross-sections A2-A2, B-B, and A1-A1, respectively, in FIG. 4. The respective process is illustrated as process 216 in the process flow 200 shown in FIG. 27. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may comprise silicon oxide, Phospho-Silicate Glass (PSG), Boro-Silicate Glass (BSG), Boron-Doped Phospho-Silicate Glass (BPSG), Undoped Silicate Glass (USG), or the like.

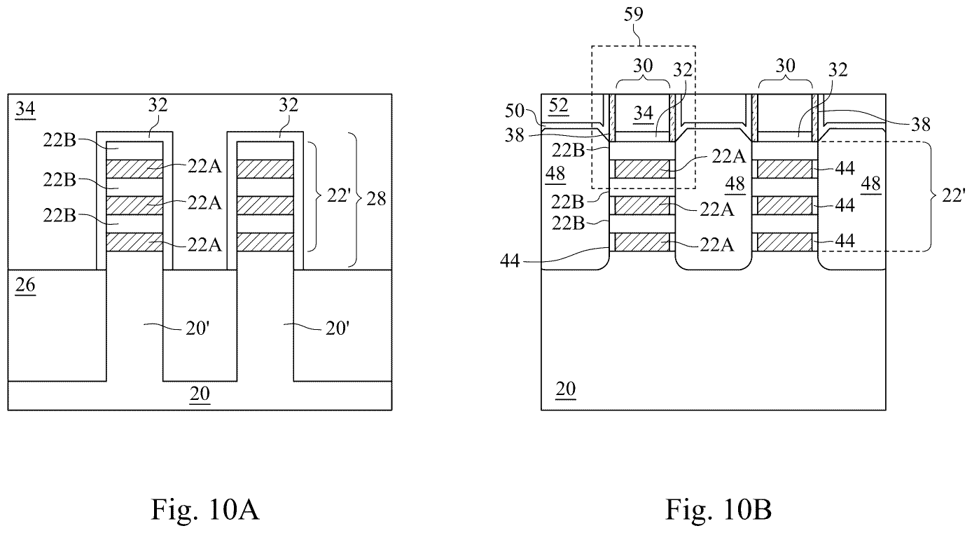

Referring to FIGS. 10A and 10B, a planarization process such as a CMP process or a mechanical grinding process is performed to level the top surface of ILD 52. The respective process is illustrated as process 218 in the process flow 200 shown in FIG. 27. In accordance with some embodiments, the planarization process may remove hard masks 36 to reveal dummy gate electrodes 34, as shown in FIG. 10B.

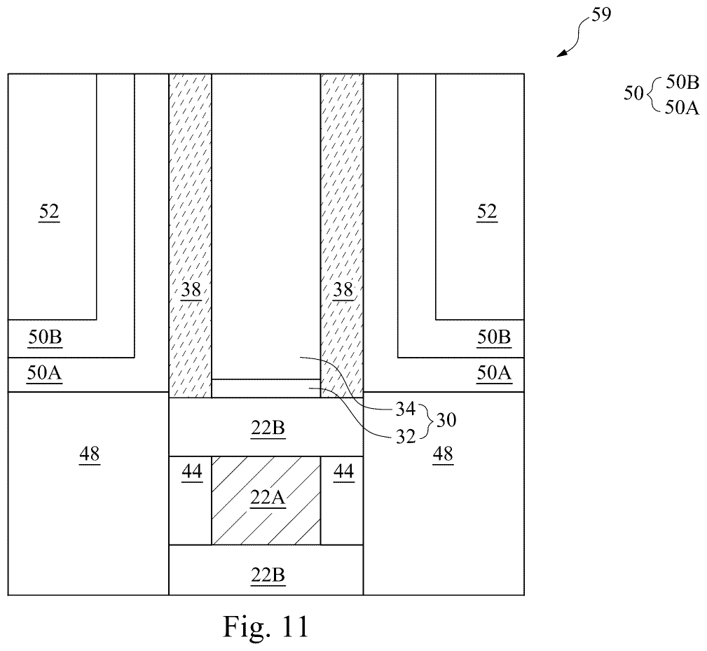

FIGS. 11 through 22, 23A, and 23B illustrate the formation of replacement gate stacks and contact plugs in accordance with some embodiments. FIG. 11 illustrates a magnified view of the region 59 in FIG. 10B. In accordance with some embodiments, CESL 50 has a dual-layer structure includes CESL layer 50A (also referred to as a lower sub-layer or a first layer), and CESL layer 50B (also referred to as an upper sub-layer or a second layer) over the CESL layer 50A. With the dual-layer structure, CESL 50 has better ability to stop etching. CESL layers 50A and 50B are formed of different materials, which are also different from the material of ILD 52. For example, CESL layer 50A may comprise an oxide-base material such as SiOC or a like material, and may (or may not) comprises nitrogen. CESL layer 50B may comprise a nitride-base material such as SiN. In accordance with alternative embodiments, CESL 50 may have a single-layer structure formed of a homogeneous dielectric material, or a tri-layer structure, with neighboring sub-layers comprising different dielectric materials.

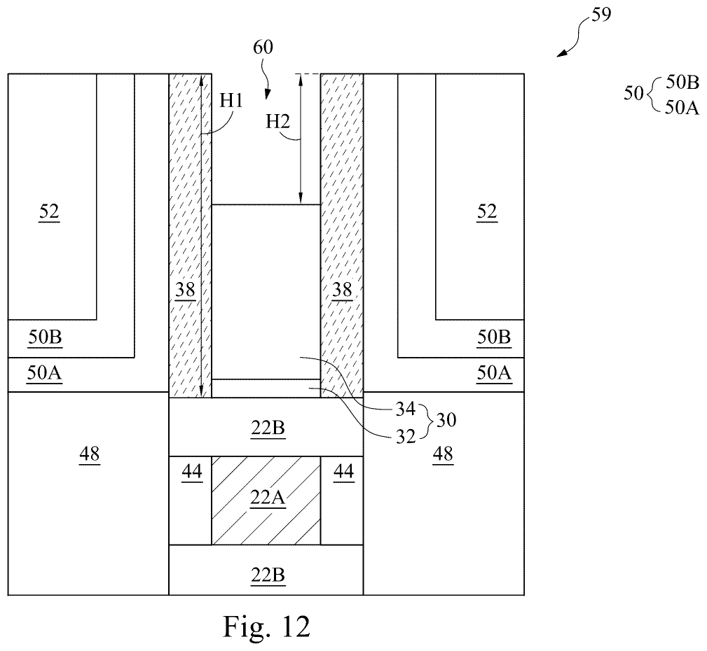

Next, as shown in FIG. 12, dummy gate electrode 34 is recessed to form recess 60. The respective process is illustrated as process 220 in the process flow 200 shown in FIG. 27. The recessing may be performed through an isotropic etching process. In accordance with some embodiments, the recessing is performed using a dry etching process, in which fluorine (F₂), hydrogen bromide (HBr), Bromine (Br₂), C₂F₆, CF₄, SO₂, the mixture of HBr, Cl₂, and O₂, or the mixture of HBr, Cl₂, O₂, and CH₂F₂ etc. may be used. Alternatively, dummy gate electrode 34 may be recessed through a wet etching process, in which KOH, tetramethylammonium hydroxide (TMAH), CH₃COOH, NH₄OH, H₂O₂, Isopropanol (IPA), the solution of HF, HNO₃, and H₂O, or the like may be used.

In accordance with some embodiments, the ratio H2/H1 ore recess 60 may be in the range between about 0.3 and about 0.7, wherein height H2 is the height of recess 60, and height H1 is the height of gate spacers 38.

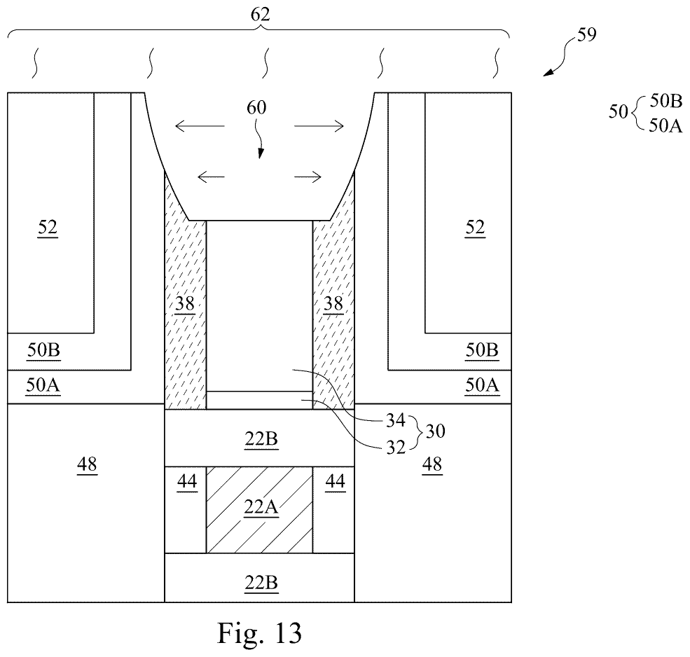

FIG. 13 illustrates the etching process 62 for the lateral expansion of recess 60. The respective process is illustrated as process 222 in the process flow 200 shown in FIG. 27. In accordance with some embodiments, the lateral recessing may be performed through an etching chemical that etches gate spacers 38. The etching chemical may also be selected so that the CESL layer 50B is not etched or etched at a much lower rate, for example, lower than about 10 percent or 5 percent of the etching rates of CESL layer 50A and gate spacers 38. In the etching of CESL layer 50B, the top surfaces of the features including ILD 52, CESL 50, and gate spacers 38 may also be lowered.

In accordance with some embodiments, the lateral expansion of recess 60 is performed through an isotropic etching process, which may be a dry etching process or a wet etching process. When the dry etching process is adopted, the mixture of NF₃ and NH₃, or the mixture of HF and NH₃ may be used as the etching gas. When the wet etching process is used, an HF solution may be used as the etching chemical. In accordance with some embodiments, recess 60 is tapered, with the upper portion being increasingly and gradually wider than respective lower portions. This profile may make the subsequent deposition processes for forming replacement gate stacks easier and with smaller chance of forming voids. The sidewalls of recess 60 may also be continuously curved.

During etching process 62, dummy gate electrode 34 may be recessed down slightly, or may not be recessed. For example, the etching rate of dummy gate electrode 34 may be lower than 20 percent of the etching rate of gate spacers 38.

As a result of the etching process 62, recess 60 is laterally expanded into gate spacers 38, and may or may not laterally extend into CESL 50. In accordance with some embodiments, the etching process 62 is controlled, so that recess 60 does not extend into ILD 52. In accordance with alternative embodiments, recess 60 also extends into ILD 52 slightly.

When the CESL 50 comprises more than one layer, recess 60 may extend into CESL layer 50A, and does not extend into CESL layer 50B in accordance with some embodiments. In accordance with alternative embodiments, recess 60 extends into both of CESL layer 50A and CESL layer 50B.

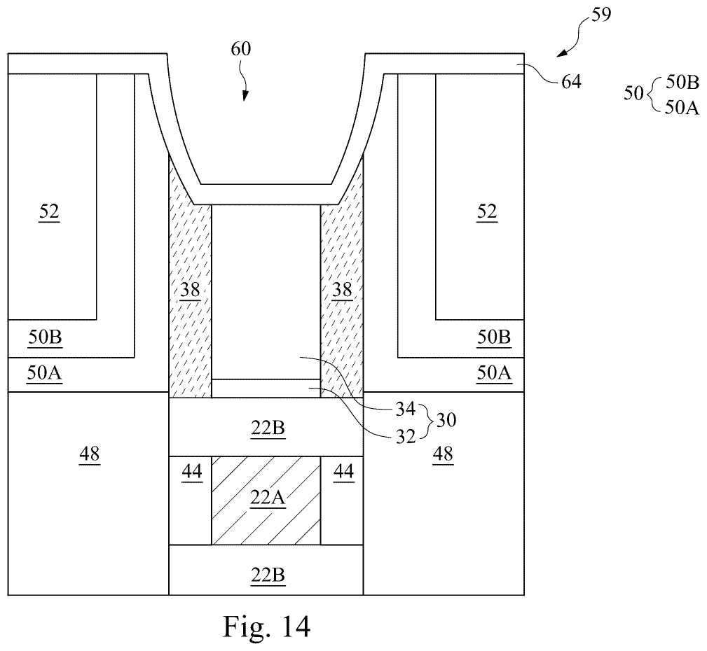

Referring to FIG. 14, protection layer 64 is deposited. The respective process is illustrated as process 224 in the process flow 200 shown in FIG. 27. In accordance with some embodiments, protection layer 64 is formed through a conformal deposition process such as ALD, CVD, or the like. The thickness of protection layer 64 may be in the range between about 1 nm and about 4 nm. The material of protection layer 64 may be different from the material of gate spacers 38, and may also be different from the material of CESL 50, and possibly the same as or different from the material of ILD 52. In accordance with some embodiments, protection layer 64 is a nitride-base dielectric layer, and may comprise SiOCN, SiN, SiON, or the like, or multi-layers thereof. For example, when having a multi-layer structure, protection layer 64 may comprise an SiOCN layer and a SiN layer over the SiOCN layer.

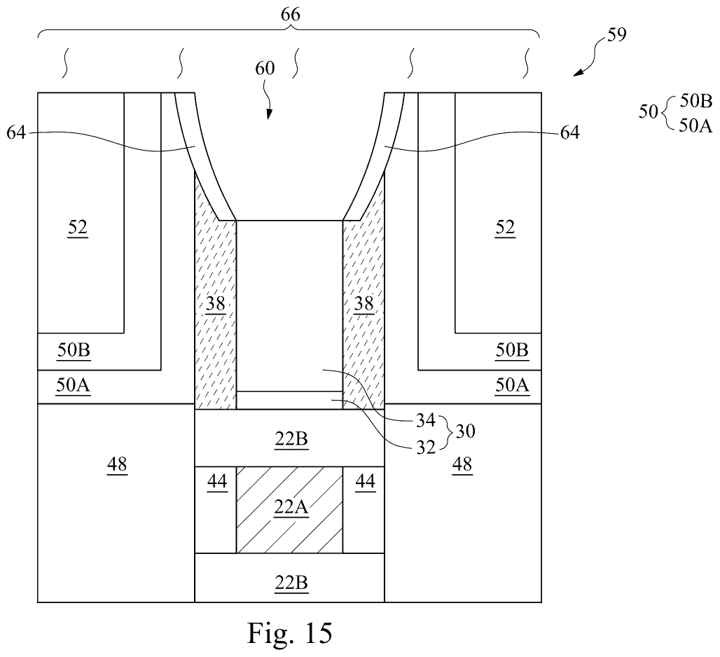

Next, as shown in FIG. 15, etching process 66 is performed to remove the horizontal portions of protection layer 64, with the vertical portions of protection layer 64 being left to form protection layers, which are also referred to as protection layers 64. The respective process is illustrated as process 226 in the process flow 200 shown in FIG. 27. When viewed in a top view of the structure, the protection layers 64 in a recess 60 may form a dielectric ring encircling recess 60.

The etching process 66 may include an anisotropic etching process. Etching process 66 and may or may not include isotropic etching component, for example, by adjusting the bias power. Depending on the material of protection layer 64, the etching gas may include a fluorine-containing gas such as CF₄, NF₃, SF₆, CHF₃, or combinations thereof. Other gases such as ClF₃, O₂, N₂, H₂, Ar, NO, and the like, may also be added. The etching chemical may have a lower etching rate for etching protection layers 64 than etching silicon oxide (for example, comprised in ILD 52). After the etching process 66, entireties of protection layers 64 may be higher than the remaining dummy gate stack 30.

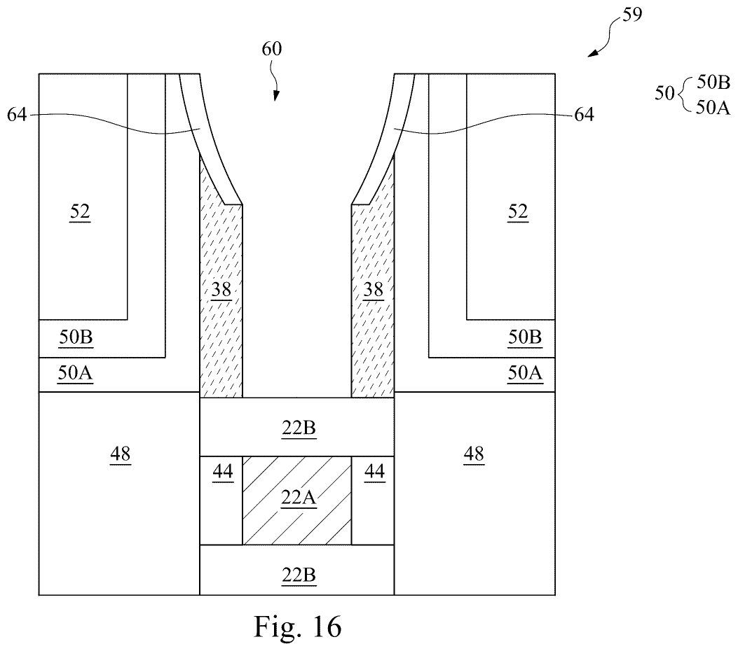

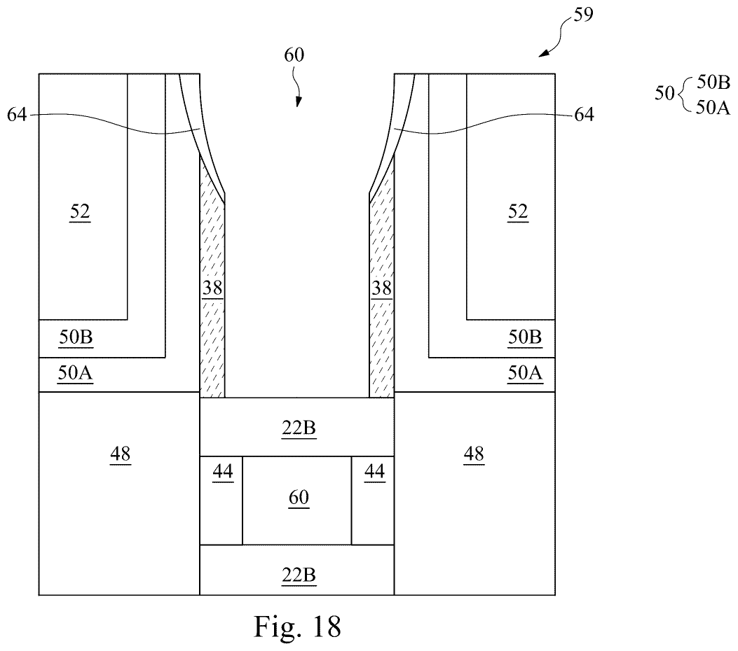

Next, dummy gate electrode 34 is removed in an etching process, so that recess 60 further extends downwardly, as shown in FIG. 16. The respective process is illustrated as process 228 in the process flow 200 shown in FIG. 27. Dummy gate dielectric 32 is thus exposed to recess 60. In accordance with some embodiments, dummy gate dielectric 32 is also removed through etching. In accordance with alternative embodiments, dummy gate dielectric 32 is not etched at this stage, and will be removed in the process shown in FIG. 18. Etching dummy gate dielectric 32 in a later stage may protect the nanostructure 22B, if needed.

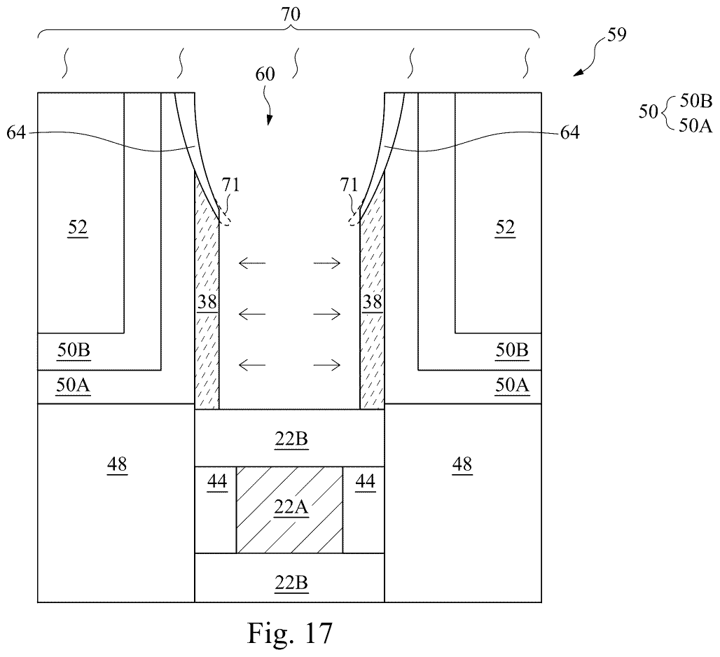

FIG. 17 illustrates the enlargement of recess 60 through etching process 70, wherein gate spacers 38 are laterally thinned. The respective process is illustrated as process 230 in the process flow 200 shown in FIG. 27. In the etching process 70, gate spacers 38 are etched in an isotropic etching process. The etching chemical is selected to be able to etch gate spacers 38, while protection layers 64 are not etched, or thinned at a much smaller etching selectivity, for example, smaller than about 5 percent of the etching rate of gate spacers 38. The etched portions may have a thickness between about 30 percent and about 50 percent the thickness before the thinning.

It is appreciated that if protection layers 64 are not formed, it is difficult to control the lateral etching of the upper parts of gate spacers 38, CESL 50 and ILD 52, which etching may cause leakage or electrical shorting between the subsequently formed gate stack and source/drain contact plugs. Protection layers 64 may act as the protection layer for protecting the upper portions of gate spacers 38, CESL 50 and ILD 52 from being laterally etched excessively.

The bottom portions of protection layers 64 may also be recessed when these portions are protruded laterally after gate spacers 38 are laterally recessed. Accordingly, the bottom ends of protection layers 64 may be flush with, or slightly protruding out of, the sidewalls of the respective underlying gate spacers 38. For example, dashed lines 71 illustrate the edges of the possible protrusion portions, and the protrusions are also referred to as protrusion portions 71 or protrusions 71. After etching process 70, protection layers 64 may have upper portions having thickness T1, and lower power having thickness T2 smaller than thickness T1. In accordance with some embodiments, ratio T1/T1 may be in the range between about 0.2 and 0.8. Thickness difference (T1−T2) may be in the range between about 1 nm and about 20 nm.

After the etching process 70, protection layers 64 may have upper portions increasingly wider (in the horizontal direction) than the respective lower portions. Alternatively stated, in a cross-sectional view of the structure, protection layers 64 may be tapered.

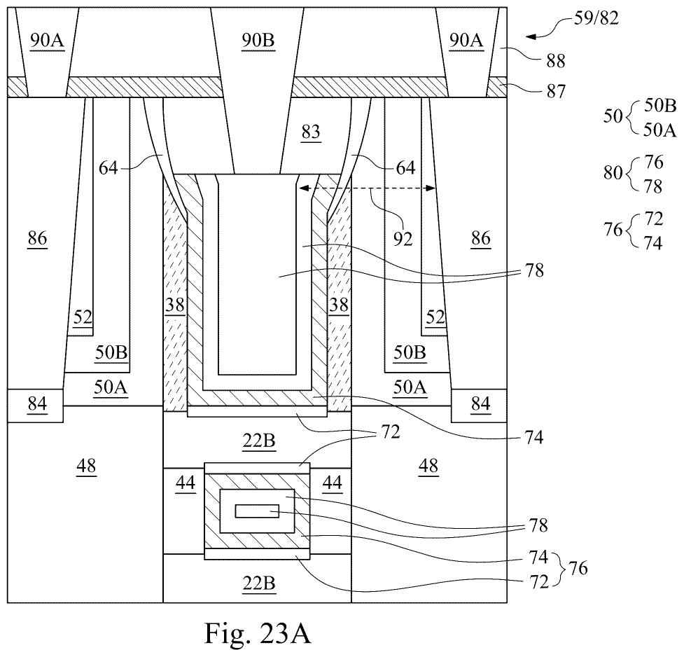

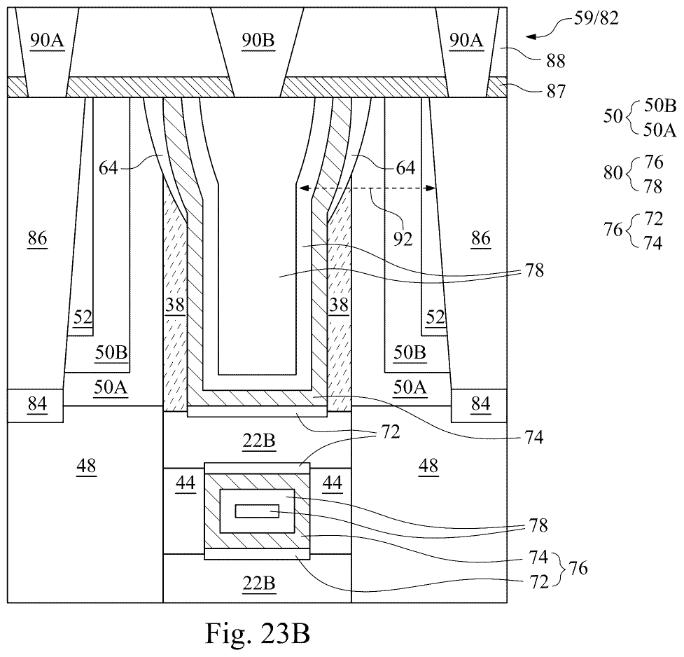

In subsequent figures, the protrusion portions 71 are not illustrated, while these portions may or may not exist in the final structure as shown in FIGS. 23A and 23B. If dummy gate dielectric 32 has not been removed in the preceding process, dummy gate dielectric 32 is removed.

Sacrificial layers 22A are then removed to extend recess 60 between nanostructures 22B, and the resulting structure is shown in FIG. 18. The respective process is illustrated as process 232 in the process flow 200 shown in FIG. 27. Sacrificial layers 22A may be removed by performing an isotropic etching process such as a wet etching process using etchants that are selective to the materials of sacrificial layers 22A. Nanostructures 22B, substrate 20, and STI regions 26, on the other hand, remain relatively un-etched as compared to sacrificial layers 22A. In accordance with some embodiments in which sacrificial layers 22A include, for example, SiGe, and nanostructures 22B include, for example, Si or SiC, etching chemicals such as tetra methyl ammonium hydroxide (TMAH), ammonium hydroxide (NH₄OH), or the like may be used to remove sacrificial layers 22A.

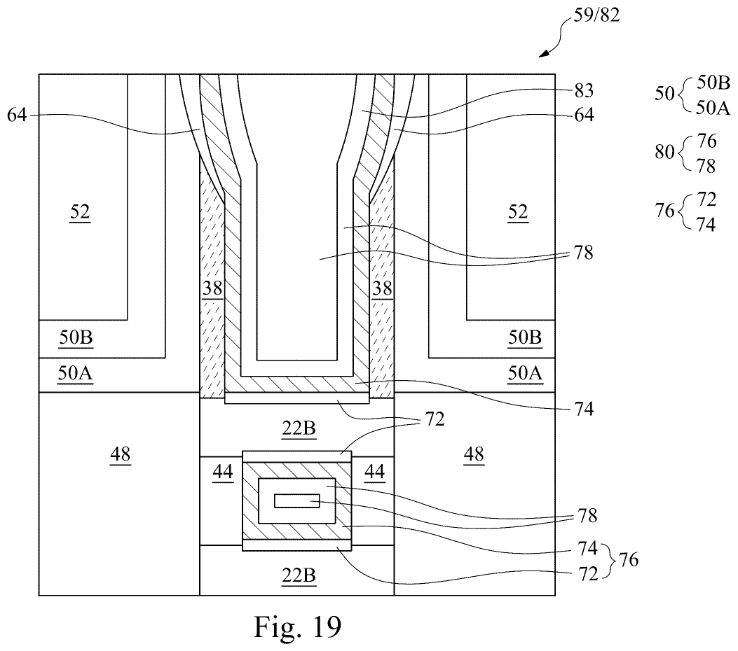

FIG. 19 illustrates the formation of replacement gate stack 80, so that transistor 82 is formed. The respective process is illustrated as process 234 in the process flow 200 shown in FIG. 27. Gate stacks 80 includes gate dielectric 76 and gate electrode 78. Gate dielectric 76 may include interfacial layer (IL) 72 and high-k dielectric layer 74. The IL 72 may comprise silicon oxide, which may be formed by thermal oxidation, chemical oxidation, deposition or the like.

High-k dielectric layer 74 may be deposited conformally in recess 60, with different portions of the high-k dielectric layer 74 having a uniform thickness. In accordance with some embodiments, high-k dielectric layer 74 is formed through a conformal deposition process such as ALD, CVD, or the like, so that the horizontal portions, the vertical portions, and the corner portions have the same thickness.

In accordance with some embodiments, high-k dielectric layer 74 may be formed of or comprise a high-k dielectric material, which may include a metal oxide or a silicate of hafnium, aluminum, zirconium, lanthanum, manganese, barium, titanium, lead, and combinations thereof.

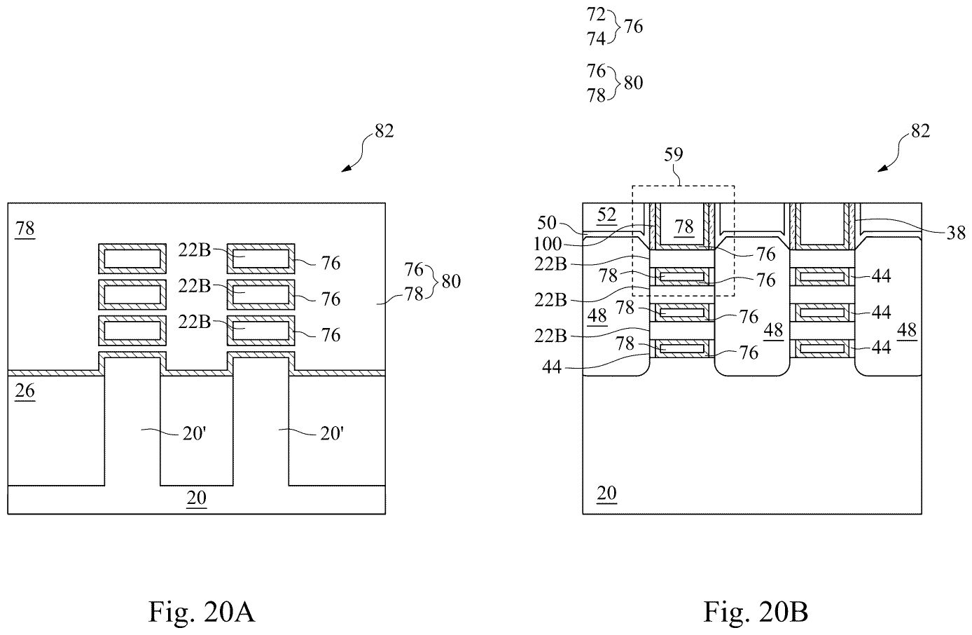

Gate electrode 78 is deposited over gate dielectric 76. Gate electrode 78 may include a metal-containing material such as TiN, TaN, TiAl, TiAlC, TiAlN, cobalt, ruthenium, aluminum, tungsten, combinations thereof, and/or multilayers thereof. Gate electrodes 78 may be deposited to fill the spaces between adjacent ones of nanostructures 22B, and fill the space between the bottom one of nanostructures 22B and the underlying substrate strips 20′ (FIGS. 20A and 20B).

After the filling of recess 60, a planarization process such as a CMP process or a mechanical grinding process is performed to remove the excess portions of the materials of gate dielectric 76 and gate electrode 78, which excess portions are over the top surface of ILD 52. Gate electrode 78 and gate dielectric 76 are collectively referred to as gate stack 80. GAA transistor 82 is thus formed.

FIGS. 20A and 20B illustrate the cross-sectional views of the GAA transistor 82. The structure shown in FIG. 19 may be obtained from the region 59 as shown in FIG. 20B. The details of the gate stack 80 is not shown in FIG. 20B, and the details may be found in FIG. 19.

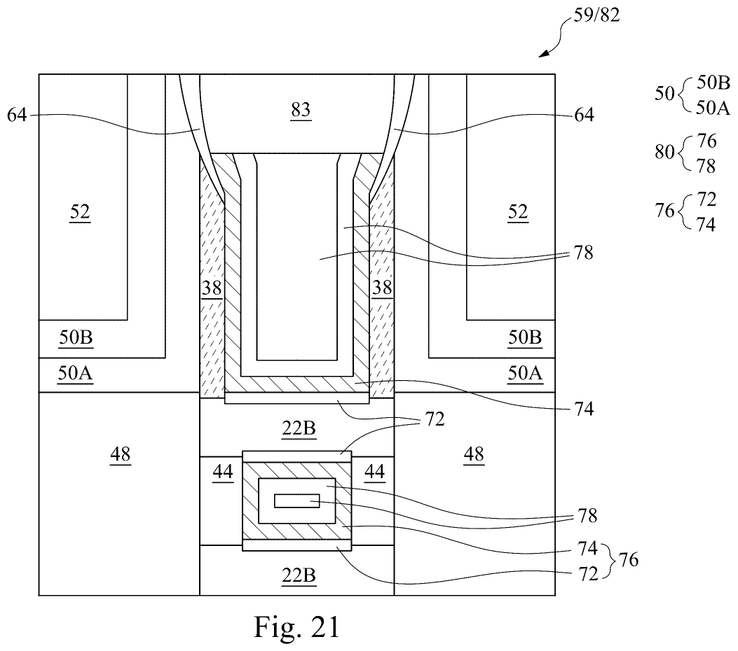

Referring to FIG. 21, hard mask 83 is formed. The respective process is illustrated as process 236 in the process flow 200 shown in FIG. 27. Hard mask 83 is formed through a self-aligned process, which includes self-aligned etching of gate stack 80 to form a recess, filling a dielectric material into the recess, and performing a planarization process to remove excess portions of the dielectric material. The dielectric material may include silicon nitride, silicon oxynitride, or the like. The self-aligned etching is performed using an chemical gas (or solution) that attach gate stack 80, but not protection layers 64, ILD 52, and ILD 52.

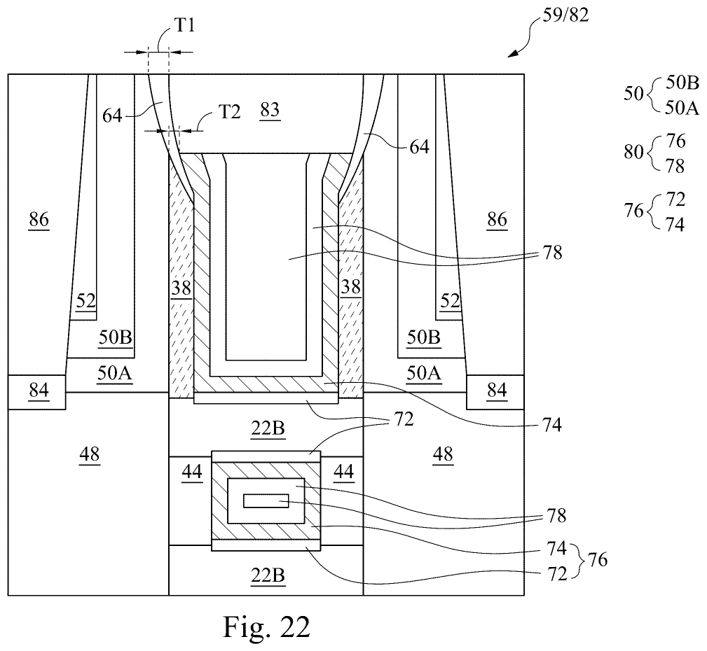

FIG. 22 illustrates the formation of source/drain silicide layers 84 and source/drain contact plugs 86. The respective process is illustrated as process 238 in the process flow 200 shown in FIG. 27. Source/drain silicide layers 84 may comprise titanium silicide, cobalt silicide, or the like. Source/drain contact plugs 86 may comprise titanium nitride, cobalt, tungsten, or the like, or multilayers thereof.

FIG. 23A illustrates the deposition of etch stop layer (ESL) 87 and (a second) ILD 88 over ILD 52 and hard mask 83. The respective process is illustrated as process 240 in the process flow 200 shown in FIG. 27. ESL 87 may comprise aluminum oxide, aluminum nitride, silicon oxycarbide, or the like, or multilayers thereof. In accordance with some embodiments, ILD 88 is formed through FCVD, CVD, PECVD, or the like. ILD 88 is formed of a dielectric material, which may be selected from silicon oxide, PSG, BSG, BPSG, USG, or the like.

FIG. 23B illustrates an embodiment in which no hard mask 83 is formed.

Source/drain contact plugs 90A and gate contact plug 90B (individually and collectively referred to as contact plugs 90) are then formed. The respective process is illustrated as process 242 in the process flow 200 shown in FIG. 27. Contact plugs 90 may each comprise one or more layers, such as a barrier layer, a diffusion layer, and a fill material. For example, in accordance with some embodiments, each of contact plugs 90A and 90B includes a barrier layer and a conductive material. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP process, may be performed to remove excess material from a surface of ILD 88.

The structure in FIGS. 23A and 23B would have suffered from leakages or electrical shorting due to the small feature sizes and hence the small distance between gate electrode 78 and source/drain contact plugs 86. Arrow 92 illustrates a possible leakage path. The leakage may also be increased when gate spacers 38 are formed of a low-k dielectric material, and thus during the recess expansion processes as shown in FIGS. 15 and 17, the gate spacers 38 may be damaged, causing the distance between gate electrodes 78 and source/drain contact plugs 86 to be too small. By forming the protection layers 64, the excess etching of gate spacers 38, CESL 50 and ILD 52 is prevented. Also, protection layers 64 may act as the block in the leakage paths. The leakage currents may be reduced, and the electrical shorting problem may be avoided.

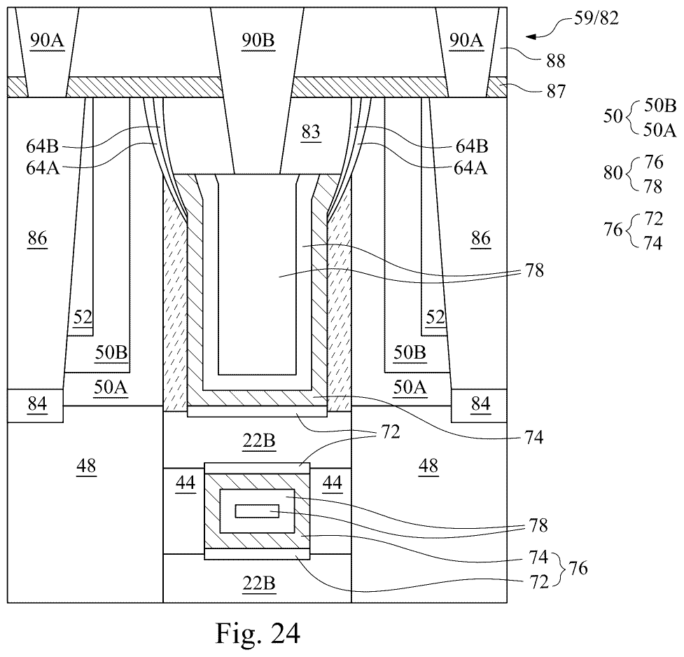

FIG. 24 illustrates the structure in accordance with alternative embodiments. These embodiments are similar to the embodiments as shown in FIG. 23A, except that protection layers 64 include a lower sub-layer 64A and an upper sub-layer 64B. The upper sub-layer 64B may have a lower etching rate than lower sub-layer 64A during the etching process 70 as shown in FIG. 17, so that the upper sub-layer 64B may provide greater protection to the lower sub-layer 64A and gate spacers 38.

In accordance with some embodiments, the upper sub-layer 64B is denser than the lower sub-layer 62A. In which embodiments, the upper sub-layer 64B and the lower sub-layer 62A may comprise a same dielectric material, with the upper sub-layer 64B having a lower porosity than the lower sub-layer 62A. In accordance with alternative embodiments, upper sub-layer 64B and the lower sub-layer 62A may comprise different dielectric materials. For example, upper sub-layer 64B may have a higher nitrogen atomic percentage than lower sub-layer 64A. In accordance with some embodiments, the upper sub-layer 64B and lower sub-layer 64A may comprise SiN and SiOCN, respectively.

In accordance with some embodiments, both of upper sub-layer 64B and lower sub-layer 64A may comprise elements such as Si, O, and N, and may or may not comprise C. The atomic percentages of the elements in upper sub-layer 64B are different from the atomic percentages of the elements in lower sub-layer 64A. For example, upper sub-layer 64B may have a higher nitrogen atomic percentage than lower sub-layer 64A, and/or lower sub-layer 64A may have a higher carbon atomic percentage than upper sub-layer 64B.

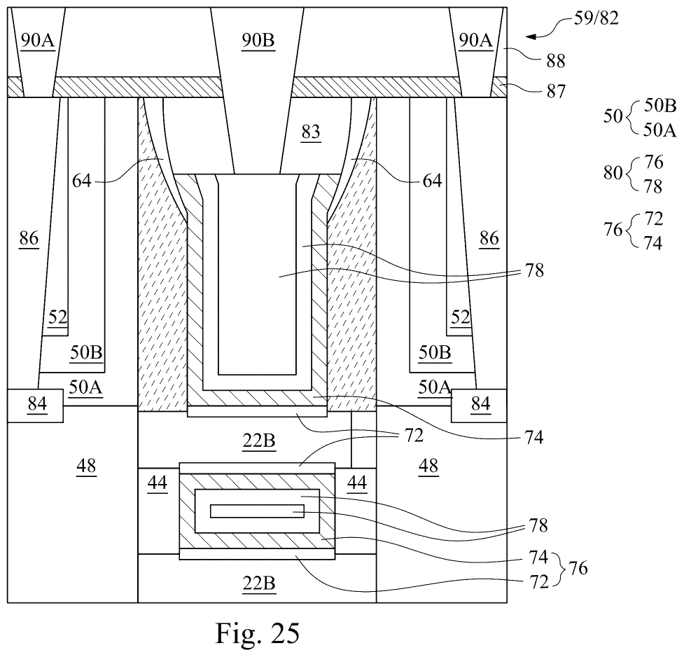

FIG. 25 illustrates a structure in accordance with alternative embodiments. The protection layers 64 in accordance with these embodiments are not in contact with CESL 50, and is spaced apart from CESL 50 by some outer portions of gate spacers 38.

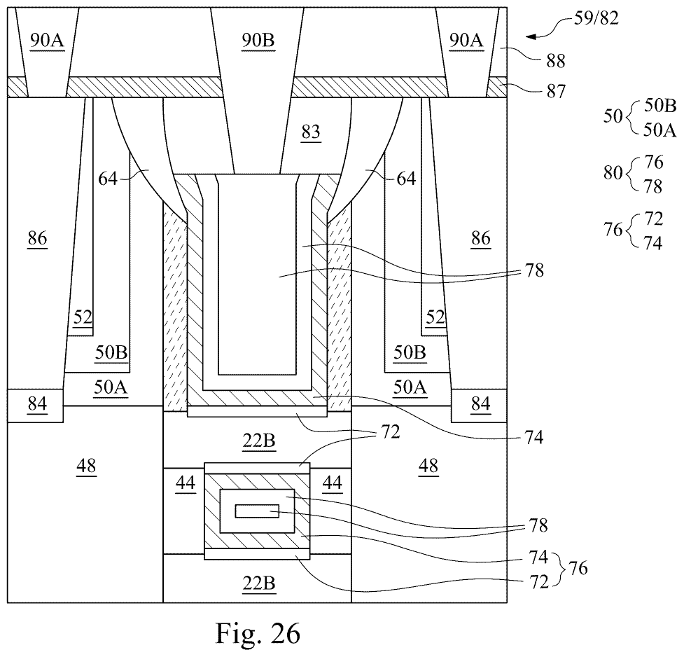

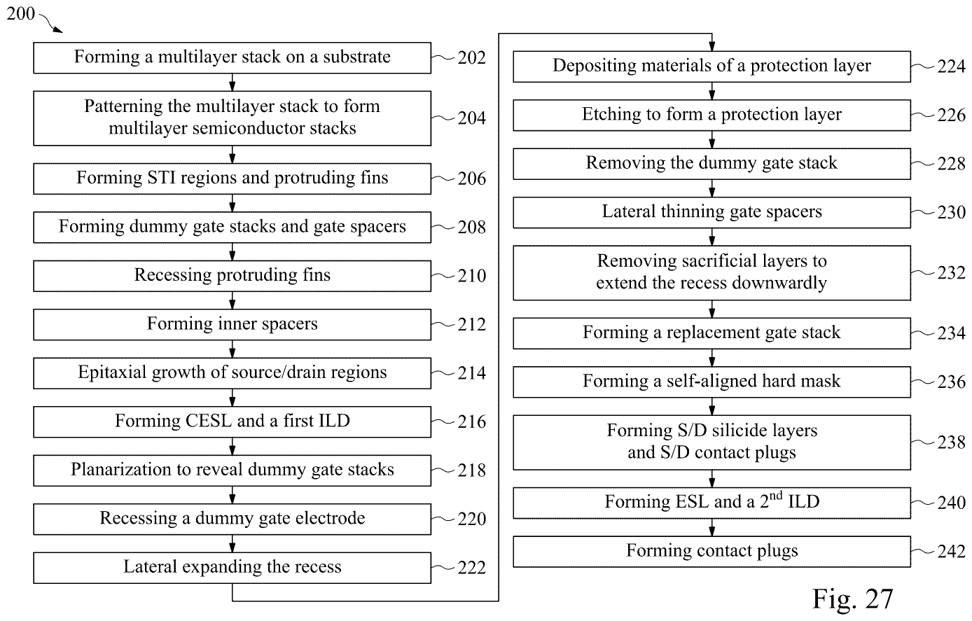

FIG. 26 illustrates a structure in accordance with alternative embodiments. The protection layers 64 in accordance with these embodiments are in contact with both of the CESL layer 50B and lower sub-layer CESL layer 50A.

The embodiments of the present disclosure have some advantageous features. By forming protection layers to protect gate spacers and the neighboring CESL and ILD, the adverse over-etch of the gate spacers and the neighboring CESL and ILD is avoided. The distance between gate electrode and the adjacent source/drain contact plug is reduced, and leakage and the possibility of electrical shorting are reduced.

In accordance with some embodiments of the present disclosure, a method comprises forming a dummy gate stack; forming gate spacers on opposing sides of the dummy gate stack; forming a contact etch stop layer, with the gate spacers being in the contact etch stop layer; forming an inter-layer dielectric over the contact etch stop layer; recessing the dummy gate stack and the gate spacers to form a recess in the inter-layer dielectric; depositing a protection layer, wherein the protection layer comprises a portion in the recess; etching the protection layer to leave a protection layer in the recess; removing the dummy gate stack to extend the recess downwardly; and forming a replacement gate stack in the recess.

In an embodiment, the recessing the dummy gate stack and the gate spacers comprises recessing the dummy gate stack; and after the dummy gate stack is recessed, etching the gate spacers. In an embodiment, the forming the contact etch stop layer comprises depositing a first sub-layer; and depositing a second sub-layer over the first sub-layer. In an embodiment, the protection layer interfaces the first sub-layer of the contact etch stop layer. In an embodiment, the protection layer further interfaces the second sub-layer of the contact etch stop layer.

In an embodiment, a bottom portion of the protection layer is laterally spaced apart from the contact etch stop layer by a part of the gate spacers, and a top portion of the protection layer physically contacts the contact etch stop layer. In an embodiment, the depositing the protection layer comprises depositing a nitride-containing dielectric layer. In an embodiment, the depositing the protection layer comprises depositing a first layer and a second layer over the first layer. In an embodiment, the method further comprises, after the removing the dummy gate stack and before the forming the replacement gate stack, laterally recessing the gate spacers.

In accordance with some embodiments of the present disclosure, a method comprises etching a dummy gate stack that is over a semiconductor region to form a recess in an inter-layer dielectric, wherein gate spacers are exposed; expanding a top portion of the recess to be wider than respective lower portions of the recess, wherein sidewalls of at least one dielectric material are exposed to the recess; forming a dielectric protection layer in the recess, wherein the dielectric protection layer contacts the sidewalls of the at least one dielectric material, and wherein the dummy gate stack is underlying and exposed to the recess; removing the dummy gate stack; thinning the gate spacers, wherein the at least one dielectric material is protected by the dielectric protection layer from being thinned laterally; and forming a replacement gate stack in the recess.

In an embodiment, the thinning the gate spacers comprises an isotropic etching process. In an embodiment, the dielectric protection layer comprises a nitrogen-containing dielectric material, and the thinning the gate spacers is performed using an etching chemical that has a higher etching rate for etching silicon oxide than etching the dielectric protection layer. In an embodiment, the dielectric protection layer is formed higher than the dummy gate stack.

In an embodiment, an entirety of the dielectric protection layer is formed being higher than the dummy gate stack. In an embodiment, the method further comprises, after the thinning the gate spacers, removing a sacrificial semiconductor layer underlying the recess, wherein the replacement gate stack comprises a part in a space left by the sacrificial semiconductor layer that has been removed.

In accordance with some embodiments of the present disclosure, a structure comprises a semiconductor layer; a gate spacer over the semiconductor layer; a gate dielectric over the semiconductor layer; a gate electrode over the gate dielectric; a dielectric hard mask over and contacting the gate electrode; a protection layer encircling, and contacting, the dielectric hard mask; a contact etch stop layer contacting the gate spacer; and an inter-layer dielectric over the contact etch stop layer. In an embodiment, the dielectric hard mask is tapered, with upper portions of the dielectric hard mask being wider than respective lower portions of the dielectric hard mask.

In an embodiment, upper portions of the protection layer are thicker than respective lower portions of the protection layer. In an embodiment, the contact etch stop layer comprises a first sub-layer; and a second sub-layer over the first sub-layer, wherein the protection layer contacts the first sub-layer and the second sub-layer. In an embodiment, the protection layer further contacts the second sub-layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a dummy gate stack;
forming gate spacers on opposing sides of the dummy gate stack;
forming a contact etch stop layer, with the gate spacers being adjacent to the contact etch stop layer;
depositing an inter-layer dielectric over the contact etch stop layer;
recessing the dummy gate stack and the gate spacers to form a recess;
depositing a protection layer, wherein the protection layer comprises a portion in the recess;
etching the protection layer, with a portion of the protection layer being left in the recess;
removing the dummy gate stack to extend the recess downwardly; and
forming a replacement gate stack in the recess.

2. The method of claim 1, wherein the recessing the dummy gate stack and the gate spacers comprises:
recessing the dummy gate stack; and
after the dummy gate stack is recessed, etching the gate spacers.

3. The method of claim 1, wherein the forming the contact etch stop layer comprises:
depositing a first sub-layer; and
depositing a second sub-layer over the first sub-layer.

4. The method of claim 3, wherein the protection layer interfaces the first sub-layer of the contact etch stop layer.

5. The method of claim 4, wherein the protection layer further interfaces the second sub-layer of the contact etch stop layer.

6. The method of claim 1, wherein a bottom portion of the protection layer is laterally spaced apart from the contact etch stop layer by a part of the gate spacers, and a top portion of the protection layer physically contacts the contact etch stop layer.

7. The method of claim 1, wherein the depositing the protection layer comprises depositing a nitride-containing dielectric layer.

8. The method of claim 1, wherein the depositing the protection layer comprises depositing a first layer and a second layer over the first layer.

9. The method of claim 1 further comprising, after the removing the dummy gate stack and before the forming the replacement gate stack, laterally recessing the gate spacers.

10. A method comprising:
expanding a top portion of a recess to be wider than respective lower portions of the recess, wherein sidewalls of at least one dielectric material are exposed to the recess, wherein gate spacers are exposed to the recess;
forming a dielectric protection layer in the recess, wherein the dielectric protection layer contacts the sidewalls of the at least one dielectric material, and wherein a dummy gate stack is underlying and exposed to the recess;
removing the dummy gate stack;
thinning the gate spacers, wherein the at least one dielectric material is protected by the dielectric protection layer from being thinned laterally; and
forming a replacement gate stack in the recess.

11. The method of claim 10, wherein the thinning the gate spacers comprises an isotropic etching process.

12. The method of claim 10, wherein the dielectric protection layer comprises a nitrogen-containing dielectric material, and the thinning the gate spacers is performed using an etching chemical that has a higher etching rate for etching silicon oxide than etching the dielectric protection layer.

13. The method of claim 10, wherein the dielectric protection layer is formed higher than the dummy gate stack.

14. The method of claim 13, wherein an entirety of the dielectric protection layer is formed being higher than the dummy gate stack.

15. The method of claim 10 further comprising, after the thinning the gate spacers, removing a sacrificial semiconductor layer underlying the recess, wherein the replacement gate stack comprises a part in a space left by the sacrificial semiconductor layer that has been removed.

16. A structure comprising:
a semiconductor layer;
a gate spacer disposed on the semiconductor layer;
a gate dielectric disposed on the semiconductor layer;
a gate electrode over the gate dielectric;
a source/drain region aside of the gate electrode and interfaces the gate spacer;
a contact etch stop layer adjacent to the gate spacer, wherein the contact etch stop layer is over and interfaces the source/drain region;
a protection layer disposed on the gate spacer and interfacing both of the gate spacer and the contact etch stop layer; and
an inter-layer dielectric over the contact etch stop layer.

17. The structure of claim 16 further comprising a dielectric hard mask over and contacting the gate electrode, wherein the dielectric hard mask is tapered, with upper portions of the dielectric hard mask being wider than respective lower portions of the dielectric hard mask.

18. The structure of claim 16, wherein upper portions of the protection layer are thicker than respective lower portions of the protection layer.

19. The structure of claim 16, wherein the contact etch stop layer comprises:
a first sub-layer; and
a second sub-layer over the first sub-layer, wherein the protection layer contacts the first sub-layer and the second sub-layer.

20. The structure of claim 19, wherein the protection layer further contacts the second sub-layer.
